(19) United States
(12) Patent Application Publication
(10) Pub. No.: US 2026/0173837 A1
(43) Pub. Date: Jun. 18, 2026

(54) DOPED CONDUCTIVE FEATURES OF AN INTERCONNECT STRUCTURE AND METHODS OF MANUFACTURING THE SAME

(71) Applicant: TEXAS INSTRUMENTS INCORPORATED, Dallas, TX (US)

(72) Inventors: Young-Joon Park, Plano, TX (US); Jonathan Metzman, Salt Lake City, UT (US); John Rodriguez, Dallas, TX (US)

(21) Appl. No.: 18/981,097

(22) Filed: Dec. 13, 2024

(51) Int. Cl. H01L 21/768; H01L 23/532

(52) U.S. Cl. CPC H10W 20/089; H10W 20/033; H10W 20/043; H10W 20/056; H10W 20/062; H10W 20/084; H10W 20/097; H10W 20/425

(57) ABSTRACT

Disclosed herein is a method including forming a trench within a dielectric layer, the trench including a first portion having a first width and a second portion having a second width that is different than the first width, forming a first doped layer in the trench, forming a first conductive material in at least the first portion of the trench, forming a second doped layer over the first conductive material, the second doped layer including a dopant, and performing a thermal treatment process, wherein the dopant of the second doped layer diffuses into the first conductive material during the thermal treatment process such that a doped conductive material is formed as a result of performing the thermal treatment process.

### FIELD

The present disclosure generally relates semiconductor devices, and more particularly, to an interconnect structure in semiconductor devices.

### BACKGROUND

Integrated circuits may include interconnect structures having conductive features, such as metal lines and vias, that connect different semiconductor components to each other within an integrated circuit. In some integrated circuits, these conductive features may form an interface with various materials including dielectric materials and other conductive features. For example, one such interface may be an adjacent dielectric film acting as a barrier layer attempting to isolate the conductive feature. In other examples, the conductive feature may be formed through an etch stop layer such that the conductive feature interfaces with the dielectric film of the etch stop layer. However, problems in an interface between a conductive feature and another material layer may affect the electrical and/or structural integrity of the integrated circuit.

### SUMMARY

Disclosed herein is a method including forming a trench within a dielectric layer, the trench including a first portion having a first width and a second portion having a second width that is different than the first width, forming a first doped layer in the trench, forming a first conductive material in at least the first portion of the trench, forming a second doped layer over the first conductive material, the second doped layer including a dopant, and performing a thermal treatment process, wherein the dopant of the second doped layer diffuses into the first conductive material during the thermal treatment process such that a doped conductive material is formed as a result of performing the thermal treatment process.

Also disclosed herein is a method including forming a trench within a dielectric layer, forming a first metal layer at least partially in the trench, forming a first doped layer over the first metal layer, the first doped layer including a first dopant, and performing a treatment process, wherein the first dopant of the first doped layer diffuses into the first metal layer during the treatment process such that a doped metal layer is formed as a result of performing the treatment process.

Also disclosed herein is a method including forming a first doped layer, the first doped layer including a first dopant, forming a first conductive layer over the first doped layer, forming a second doped layer over the first conductive layer, the second doped layer including a second dopant, forming a second conductive layer over the second doped layer, and after forming the second conductive layer, performing a treatment process, wherein the first and second dopants diffuse into the first conductive layer and the second conductive layer such that a doped conductive material is formed as a result of performing the treatment process.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a cross section view of a semiconductor device, in accordance with various examples.

FIG. 2 illustrates a flowchart for a method forming a semiconductor device, in accordance with various examples.

FIGS. 3A, 3B, 3C, 3D, 3E, 3F, 3G, and 3H illustrate cross-section views of a semiconductor device, in accordance with the process of FIG. 2, and the various examples associated therewith.

FIG. 4 illustrates a flowchart for a method forming a semiconductor device, in accordance with various examples.

FIGS. 5A, 5B, 5C, 5D, and 5E illustrate cross-section views of a semiconductor device, in accordance with the process of FIG. 4, and the various examples associated therewith.

FIG. 6 illustrates a flowchart for a method forming a semiconductor device, in accordance with various examples.

FIGS. 7A, 7B, 7C, 7D, and 7E illustrate cross-section views of a semiconductor device, in accordance with the process of FIG. 6, and the various examples associated therewith.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate one or more intervening layers between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

The present disclosure relates generally, but not exclusively, to semiconductor processing for forming interconnect structures that helps resolve electromigration and manage via stress. In that regard, interconnect structures may include conductive features such as metal lines and vias that connect different semiconductor components to each other within an integrated circuit. The conductive features, in various examples, may include a barrier layer and a doped conductive layer. Forming the conductive feature may include forming a trench in a dielectric material (e.g., an interlevel dielectric layer) of a substrate, forming the barrier layer (e.g., tantalum nitride (TaN) layer) over the dielectric material including within the trench, forming a doped seed layer (e.g., copper seed layer including aluminum (Al), manganese (Mn), magnesium (Mg), etc.) over the barrier layer, forming a conductive layer (e.g., copper (Cu)) over the doped seed layer. Subsequently, a thermal process (e.g., annealing) may be performed to the substrate and the dopant from the doped seed layer may diffuse into the conductive layer as a result of the thermal process.

Doping the conductive layer of the conductive feature tends to decrease electromigration and reduce via stress migrations in an interconnect structure. In that regard, the dopant tends to migrate (or accumulate) at grain boundaries of the conductive layer and/or interfaces between the conductive feature and another material layer (e.g., a dielectric layer) surrounding the conductive feature. This dopant migration reduces electromigration and/or via stress migrations in the conductive feature and/or in the interconnect structure. In various examples, increasing the dopant concentration in the doped conductive layer provides additional dopant which improves effectiveness of the dopant in reducing electromigration and/or via stress migrations.

Generally, there are two ways to increase the dopant concentration in the doped conductive layer of a conductive feature; i) increasing the thickness of the doped seed layer and/or ii) increasing the dopant concentration in the doped seed layer. Both increase the quantity of the dopant available to diffuse into the conductive layer, in doing so increasing the dopant concentration within the doped conductive layer. However, there is an upper limit to the usable thickness of the doped seed layer, namely the size of the opening (or width) of the trench in which the conductive feature is formed therein. At, or above, a certain thickness, the doped seed layer will pinch off, or close, the opening to the trench. This pinch off prevents the formation of the conductive layer and, in various examples, may leave a void, or air gap, within the trench. Similarly, the dopant concentration in the material used for the doped seed layer (e.g., acquiring/preparing a sputter target including greater dopant concentration) tends to be limited and/or inefficient in a high volume manufacturing environment.

To address these issues, disclosed herein are methods of forming a doped conductive feature having a higher dopant concentration than would otherwise be available given the thickness and starting dopant concentration limitations. In some examples, the disclosed methods may be used in a dual damascene process that forms a via and a trench thereover in a dielectric layer that are subsequently filled with conductive material(s). In some examples, the disclosed methods may be used with other interconnect manufacturing processes.

The methods disclosed herein describe forming a first doped seed layer over a barrier layer disposed within a trench formed in a dielectric material. A conductive layer is then formed over the first doped seed layer, including forming an overburden (e.g., a portion of the conductive layer) over a top surface of the dielectric material. A second doped seed layer is formed over the overburden of the conductive layer. During a subsequent thermal process, the dopant from the first and second doped seed layers may diffuse into the conductive layer to form a doped conductive layer. The additional available dopant from the second doped seed layer increases the quantity (or overall availability/concentration) of the dopant which increases the dopant concentration throughout the doped conductive layer.

Also, the additional dopant provided by the second doped layer lessens the design requirements of forming the conductive feature having a doped conductive layer within a trench. Specifically, two (or more) doped seed layers, being used as a source of the dopant, allow for a thinner (e.g., less thick) first doped seed layer to be used within the trench. A thinner first doped seed layer occupies less space within the trench which reduces the chances of a pinch off effect from occurring. As a result, the subsequently formed conductive layer more adequately fills the trench as there is no pinch off effect from the first doped seed layer preventing the conductive layer from filling the trench. Moreover, the additional available dopant from the second doped seed layer ensures that the dopant from the first doped seed layer remains in the trench and does not migrate to the portion of the conductive layer over the top surface of the dielectric (e.g., overburden) where the dopant will be subsequently removed (e.g., during a chemical mechanical polishing (CMP) process).

In various examples, such as those associated with a dual damascene process, a first doped seed layer may be formed over a barrier layer disposed within a via and a trench. A first portion of a conductive layer may then be formed in the via. A second doped seed layer may then be formed over the first portion of the conductive layer. A second portion of the conductive layer may then be formed within the trench and over the second doped seed layer. During a subsequent thermal process, the dopant may diffuse into the conductive layer to form the doped conductive layer. The position of a second doped seed layer within the trench increases the quantity (or overall availability/concentration) of the dopant which increases concentration of the dopant throughout the conductive layer. Similar to the description above, because the additional dopant is provided by the second doped layer, the second doped layer allows for a thinner (e.g., less thick) first doped seed layer to be used within the via. A thinned first doped seed layer occupies less space within the via which reduces the occurrence of a pinch off effect from occurring. As a result, the subsequently formed first portion of the conductive layer more adequately fills the via as there is no pinch off effect from the first doped seed layer preventing the conductive layer from filling the via.

In various other examples, such as those associated with a dual damascene process, a first doped seed layer may be formed over a barrier layer disposed within a via and a trench. A first portion of the conductive layer may fill the via and the trench and a second doped seed layer may be formed over the overburden of the first portion of the conductive layer. A second portion of the conductive layer may then be formed over the second doped seed layer and the overburden of the first portion of the conductive layer. During a subsequent thermal process, the dopant may diffuse into the first portion of the conductive layer to form a doped conductive layer. The position of a second doped seed layer over the overburden of the first portion of the conductive layer increases the quantity (or overall availability/concentration) of the dopant which increases concentration of the dopant throughout the conductive layer. Similar to the description above, because the additional dopant is provided by the second doped layer, the second doped layer allows for a thinner (e.g., less thick) first doped seed layer to be used within the via. A thinned first doped seed layer occupies less space within the via which reduces the occurrence of a pinch off effect from occurring. As a result, the subsequently formed first portion of the conductive layer more adequately fills the via as there is no pinch off effect from the first doped seed layer preventing the conductive layer from filling the via.

Other combinations and variations, including using more than two doped seed layers are within the scope of this disclosure. Using two or more doped seed layers as described herein increases the concentration of the dopant into conductive layer and reduces electromigration and/or via stress migration. Also, in some examples, each doped seed layer may contain the same dopant or a different dopant between the various layers.

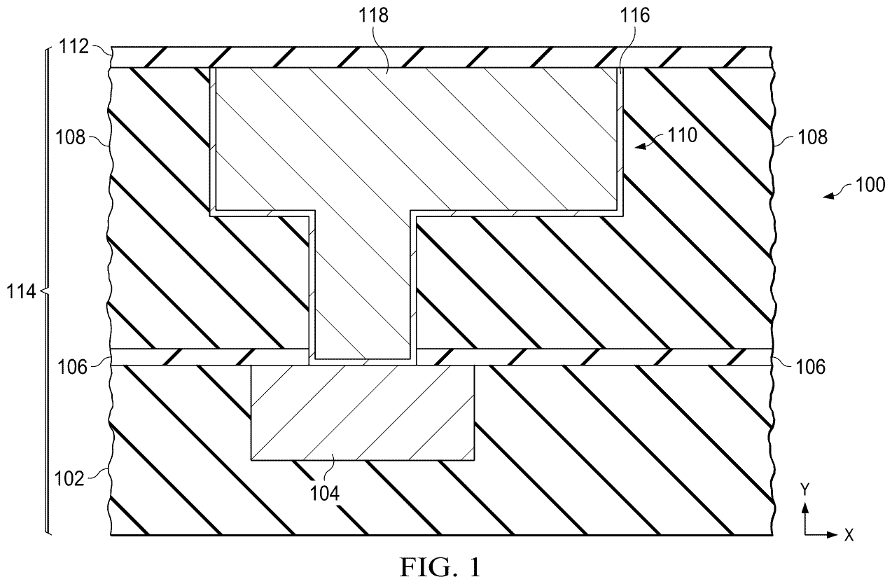

Referring now to FIG. 1, a diagrammatic cross-sectional view of a device 100 is illustrated according to various aspects of the present disclosure. In various examples, device 100 is or may be a part of a larger semiconductor device including multiple levels, metal lines, conductive interconnections, field effect transistors (FETs), dielectric materials, and/or other materials and/or structures. Additional features can be added to device 100, and some features described below can be replaced, modified, or eliminated in other examples of device 100.

As described below, device 100 incorporates a doped conductive feature that is formed using methods that improve (e.g., increase) a dopant concentration within the doped conductive feature. The improved dopant concentration of the doped conductive feature (e.g., the copper-based material) may ameliorate electromigration and/or stress related issues that may otherwise be associated with lower dopant concentration within the doped conductive feature. Some examples of stress related issues that may be mitigated by using the methods disclosed herein include via stress migration (VSM), via chain shorts (VCS), and stress induced voiding (SIV).

Device 100 includes a first dielectric layer 102, a conductive feature 104, a first etch stop layer 106, a second dielectric layer 108, a doped conductive feature 110, and a second etch stop layer 112 all of which may collectively form part of an interconnect structure 114. Doped conductive feature 110 includes a barrier layer 116 and a doped conductive material 118. As described below, interconnect structure 114 may be formed over a substrate (or semiconductor substrate) having various components formed thereon such as field effect transistors (FETs), NPN transistors, resistors, inductors, capacitors, etc. Interconnect structure 114 may be used to connect various components formed over or in such a semiconductor substrate.

First dielectric layer 102 (or first interlayer dielectric layer) may be formed over a substrate. In various examples, the substrate may include a semiconductor material, source and drain regions formed in the semiconductor material, and a gate stack formed over the semiconductor material. In various examples, the substrate may further include one or more contacts and/or metal lines formed over the source region, the drain region, and the gate stack. In various examples, first dielectric layer 102 layer may include silicon oxide, silicon nitride, silicon oxynitride, a silicon oxide-based material (such as a phosphosilicate glass (PSG) or a tetraethyl orthosilicate (TEOS) oxide), polytetrafluoroethylene, low-k dielectric layers, any other dielectric material, or any combination thereof.

Conductive feature 104 is disposed within first dielectric layer 102. In some examples, conductive feature 104 may be a metal line, via, or contact. In various examples, conductive feature 104 may connect to one or more source/drain contacts, gate contacts, and/or other conductive features that are disposed over or in a substrate. In various examples, a trench is formed in first dielectric layer 102 and conductive feature 104 is then formed in the trench. In various examples, the trench may be formed in first dielectric layer 102 using one or more etching processes. Conductive feature may each include (i) one or more metal-barrier and/or adhesion layers (e.g., titanium (Ti), titanium nitride (TiN), tantalum (Ta), tantalum nitride (TaN), the like, or a combination thereof) conformally in a respective trench in first dielectric layer 102 and (ii) a fill metal (e.g., tungsten (W), copper (Cu), silver (Ag), gold (Au), aluminum (Al), the like, or a combination thereof) over and/or on the metal-barrier and/or adhesion layer(s).

First etch stop layer 106 (or dielectric layer) is formed over first dielectric layer 102 and conductive feature 104. In various examples, first etch stop layer 106 may include silicon nitride (SiN), silicon dioxide (SiO₂), silicon carbon nitride (SiCN), aluminum oxide (AlO), silicon carbide (SiC), the like, or any combination thereof. In various examples, first etch stop layer 106 may be formed of one or more layers. First etch stop layer 106 may be formed using one or more processes. In various examples, the one or more processes may include chemical vapor deposition (CVD), atomic layer deposition (ALD), physical vapor deposition (PVD), the like, or any combination thereof.

Second dielectric layer 108 (or second interlayer dielectric layer) is formed over first etch stop layer 106. Second dielectric layer 108 may be formed similar to first dielectric layer 102. In various examples, second dielectric layer 108 may include similar materials as first dielectric layer 102. In various examples, second dielectric layer 108 may include different materials than first dielectric layer 102.

Doped conductive feature 110 is formed within second dielectric layer 108. Doped conductive feature 110 includes a barrier layer 116 and a doped conductive material 118.

Second etch stop layer 112 is formed over second dielectric layer 108 and doped conductive feature 110, including over barrier layer 116 and doped conductive material 118.

Barrier layer 116 of doped conductive feature 110 is disposed alongside surfaces of second dielectric layer 108 and first etch stop layer 106 and over conductive feature 104. In various examples, barrier layer 116 may include titanium (Ti), titanium nitride (TiN), tantalum (Ta), tantalum nitride (TaN), the like, or a combination thereof. In various examples, barrier layer 116 may be formed by a physical vapor deposition (PVD), a chemical vapor deposition (CVD) process, other suitable processing techniques, or a combination thereof.

Doped conductive material 118 of doped conductive feature 110 includes a metal and/or metal alloy and a dopant. In various examples, the metal and/or metal alloy may include tungsten (W), copper (Cu), silver (Ag), gold (Au), aluminum (Al), the like, or any combination thereof. In various examples, the dopant may include aluminum (Al), manganese (Mn), magnesium (Mg), the like, or any combination thereof. By doped conductive material 118 (e.g., Cu) having a dopant (e.g., aluminum (Al), manganese (Mn), magnesium (Mg), etc.) therein, doped conductive feature 110 tends to decrease electromigration and reduce via stress migrations in interconnect structure 114. In that regard, the dopant in doped conductive material 118 tends to migrate (or accumulate) at grain boundaries of the doped conductive material 118 and/or interfaces between the doped conductive material 118 and a surrounding material layer (e.g., barrier layer 116, second dielectric layer 108, second etch stop layer 112, etc.). This dopant migration reduces electromigration and/or via stress migrations in the conductive feature and/or in the interconnect structure. In various examples, increasing the dopant concentration in the doped conductive material 118 provides additional dopant which improves effectiveness of the dopant in reducing electromigration and/or via stress migrations.

Second etch stop layer 112 (or dielectric layer) may be formed in similar processes to those described above with respect to first etch stop layer 106. Accordingly, second etch stop layer 112 may have similar physical properties as described above with respect to first etch stop layer 106.

As shown, doped conductive feature 110 extends from conductive feature 104, through first etch stop layer 106, and second dielectric layer 108 to second etch stop layer 112. As described above, first etch stop layer 106 acts as an etch stop layer during the formation of doped conductive feature 110. In that regard, a first etching process may be used to form an opening into second dielectric layer 108 that stops on first etch stop layer 106. In various examples, one or more etching processes may be performed to form the opening. For example, a first etching process may be used to form the opening in second dielectric layer 108. Then a second etching process may be performed to etch through first etch stop layer 106 exposing a top surface of conductive feature 104. In other examples, a dual damascene process may be implemented to form the opening into second dielectric layer. As such, the opening may include a via portion and a trench portion disposed within second dielectric layer 108. Doped conductive feature 110 is then formed in such openings, including in the via and the trench, and over the exposed conductive feature 104.

As described in more detail below, disclosed herein are methods of forming a doped conductive feature using multiple doped seed layers. The use of multiple doped seed layers in forming the doped conductive feature increases concentration of the dopant in the conductive layer of the doped conductive feature mitigating electromigration and/or other via stress issues that may otherwise occur due to insufficient amount of the dopant in the doped conductive layer of the doped conductive feature.

Additionally, using multiple doped seed layers also alleviates some process constraints (e.g., spacing and size requirements) in forming the doped conductive feature. For example, a thick single doped seed layer may be used to provide the desired concentration of the dopant for forming a doped conductive feature. However, a thick doped seed layer may present process challenges especially when forming doped conductive features in smaller, or narrower, vias because a thick doped seed layer may pinch off the opening to the via. Because the present disclosure implements multiple doped seed layers, the design requirements of forming a thicker doped seed layer in vias are removed, for example in a dual damascene process, due to the additional dopant provided by a second (or more) doped layer disposed over the via.

Specifically, two (or more) doped seed layers, being used as a source of the dopant, allow for a thinner (e.g., less thick) first doped seed layer to be used within a via during a dual damascene process. A thinned (or thinner) first doped seed layer occupies less space within the via which reduces the chances of the first doped seed layer pinching off, or closing, the opening to the via. As a result, the subsequently formed conductive layer of the doped conductive feature more adequately fills the via as there is no pinch off effect from the first doped seed layer preventing the conductive layer from filling the via. Moreover, because a second (or more) doped seed layer is formed over the via, the desired dopant concentration within the doped conductive feature can still be achieve even though a thinner (e.g., containing a lower amount of dopant in view of a less total volume of the doped seed layer) first doped seed layer is formed within the via as part of forming the doped conductive feature. That is, as described below, the use of multiple doped seed layers in forming a doped conductive feature allows for a greater concentration of the dopant to be present in the doped conductive layer of the doped conducting feature while ameliorating the pinch off concern typically associated with using thicker doped seed layers that may provide a greater quantity of dopant atoms.

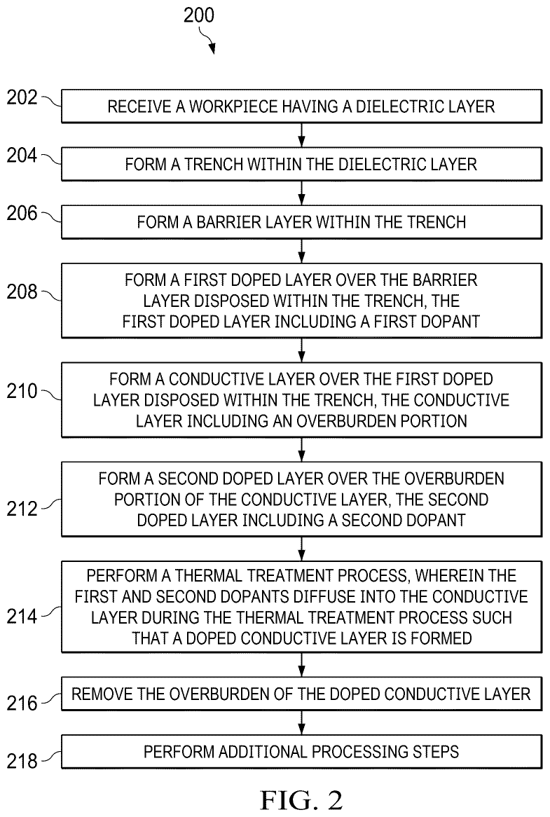

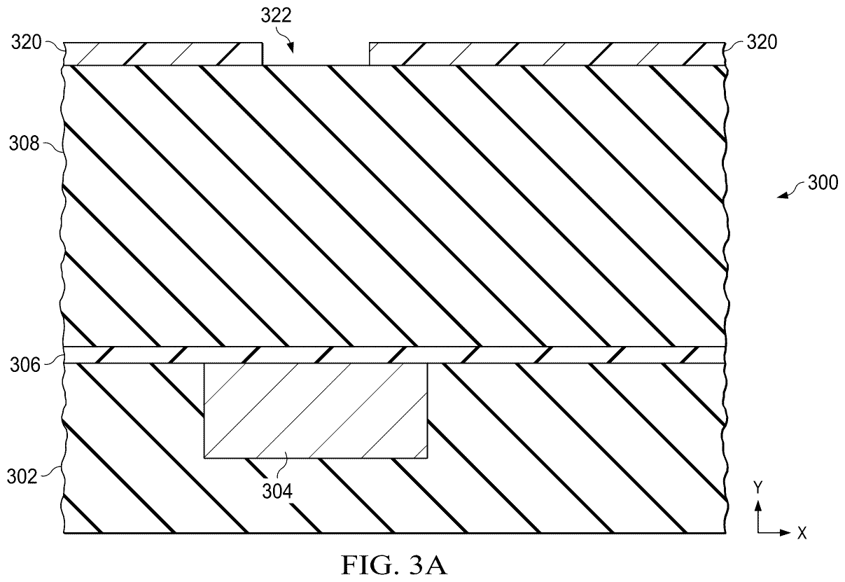

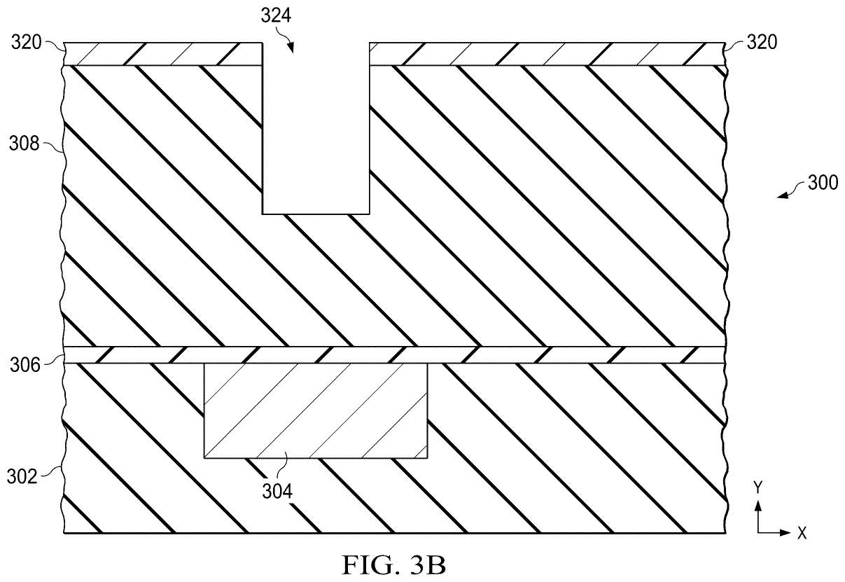

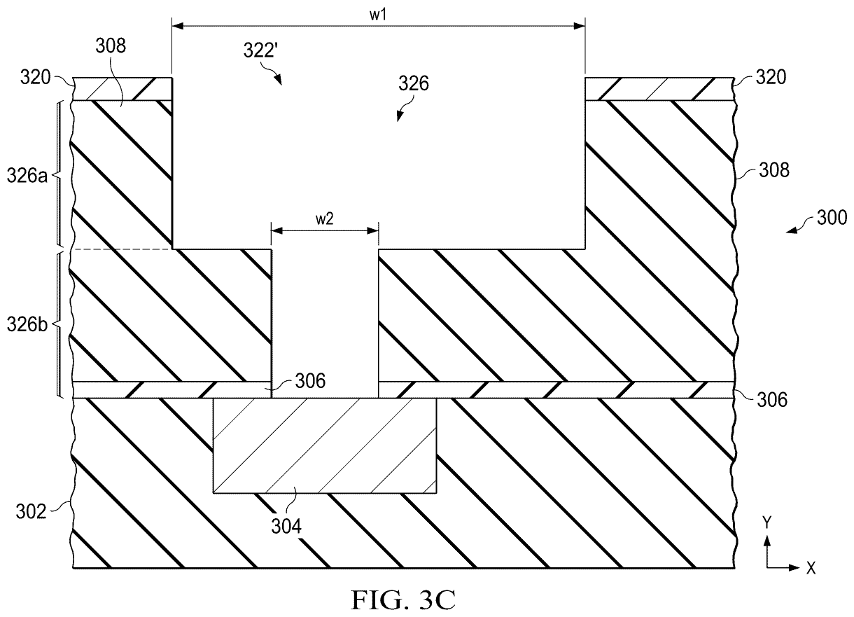

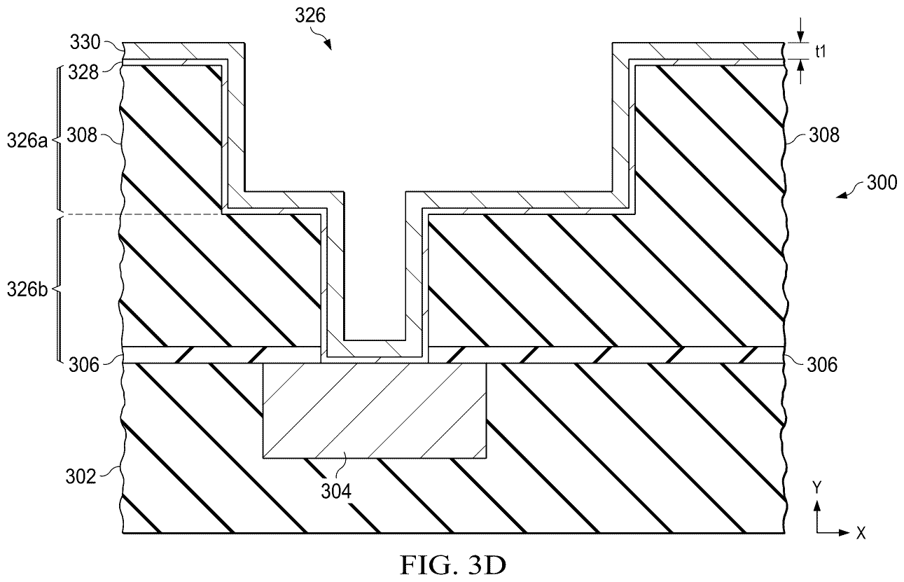

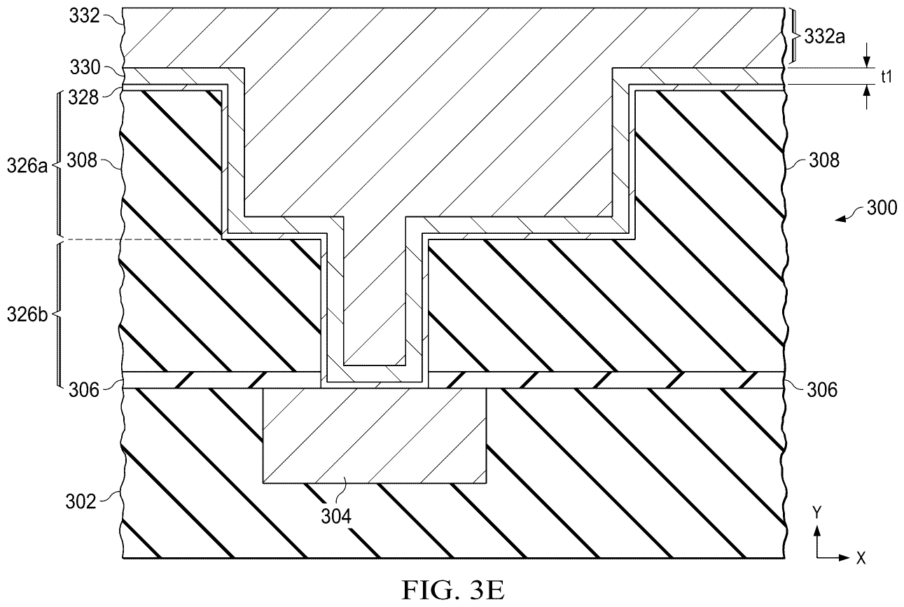

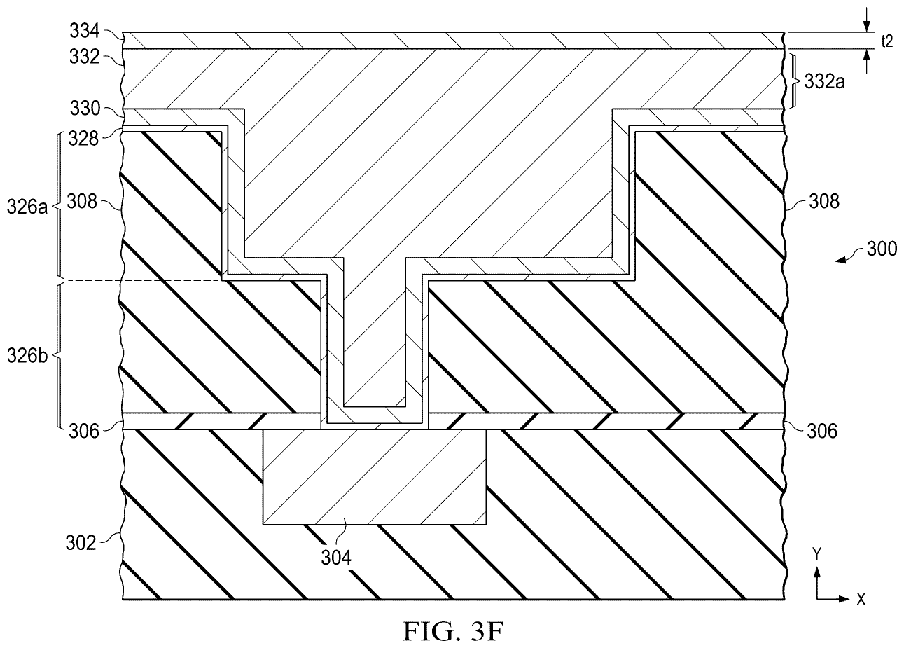

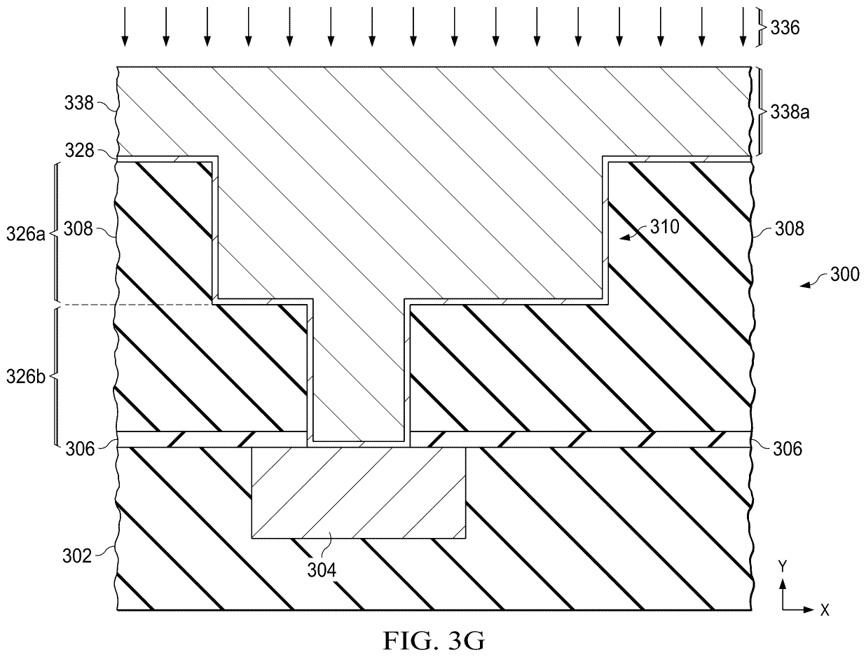

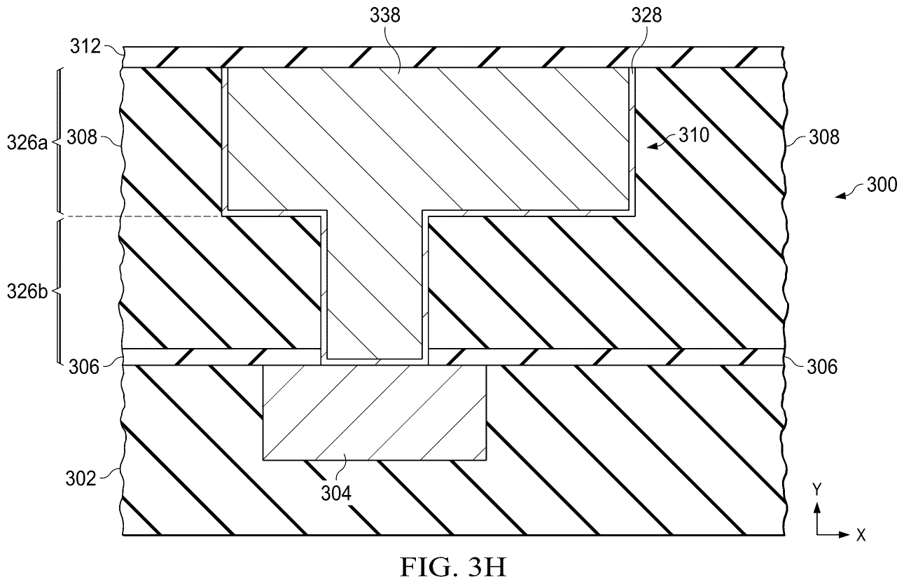

Referring now to FIG. 2, a flow diagram of a method 200 for forming an interconnect structure over a semiconductor device (e.g., a field effect transistor (FET)) is illustrated, in accordance with various examples of the present disclosure. In various examples, method 200 may be used to form an interconnect structure (e.g., interconnect structure 114) including a doped conductive feature (e.g., doped conductive feature 110) over and/or on various material layers including other dielectric layers and conductive layers associated with integrated circuit components. Additional processes can be provided before, during, and after method 200. In various examples, method 200 may be used to form a portion of device 100, described above in FIG. 1. As described below, method 200 is described with reference to FIGS. 3A-3H.

As described above, the present disclosure relates generally, but not exclusively, to semiconductor processing for forming interconnect structures that helps resolve electromigration and manage via stress. In that regard, interconnect structures may include conductive features such as metal lines and vias that connect different semiconductor components to each other within an integrated circuit. The conductive features, in various examples, may include a barrier layer and doped conductive layer. Doping the conductive layer tends to decrease electromigration and reduce via stress migrations. The dopant tends to accumulate at grain boundaries and/or interfaces which results in reduced electromigration and/or via stress migrations.

Generally, there are two ways to increase the dopant concentration in the doped conductive layer of a conductive feature: i) increasing the thickness of the doped seed layer and/or ii) increasing the dopant concentration in the doped seed layer. Both increase the quantity of the dopant available to diffuse into the conductive layer, in doing so increasing the dopant concentration within the doped conductive layer. However, there is an upper limit to the usable thickness of the doped seed layer, namely the size of the opening (or width) of the via (or trench) in which the conductive feature is formed therein. At, or above, a certain thickness, the doped seed layer will pinch off, or close, the opening to the via (or trench). This pinch off prevents the formation of the conductive layer and, in various examples, may leave a void, or air gap, within the via (or trench). Similarly, the dopant concentration in the material used for the doped seed layer (e.g., acquiring/preparing a sputter target including greater dopant concentration) tends to be limited and/or inefficient in a high volume manufacturing environment.

To address these issues, disclosed herein are methods of forming a doped conductive layer having a higher dopant concentration than would otherwise be available given the thickness and starting dopant concentration limitations. In some examples, the disclosed methods may be used in a dual damascene process that forms a via and a trench thereover in a dielectric layer that are subsequently filled with conductive material. In some examples, the disclosed methods may be used with other interconnect manufacturing processes.

In that regard, FIGS. 3A-3H are diagrammatic cross-sectional views of a device 300 at various stages of fabrication (such as those associated with method 200 of FIG. 2) according to various aspects of the present disclosure. In various examples, device 300 may be an integrated circuit device that includes various transistors such as a field effect transistor (FET) that are connected via an interconnect structure. Additional features can be added to device 300, and some features described below can be replaced, modified, or eliminated in other examples of device 300. In various examples, device 300 may be a portion of device 100 described above in FIG. 1.

At step 202, a workpiece having a dielectric layer is received. As shown in FIG. 3A, device 300 includes similar layers and materials as device 100 including a first dielectric layer 302, a conductive feature 304, a first etch stop layer 306 (or dielectric layer), and a second dielectric layer 308, descriptions of which may not be repeated below. Device 300 further includes a patterned material layer 320 formed over second dielectric layer 308. In various examples, patterned material layer 320 may include a photoresist material, a hard mask, the like, or any combination thereof. An opening 322 is formed through patterned material layer 320 exposing a top surface of second dielectric layer 308. In various examples, opening 322 may be formed using one or more etching process to remove a portion of patterned material layer 320 to expose second dielectric layer 308.

At step 204, a trench is formed within the dielectric layer. As shown in FIG. 3B, a trench 324 is formed in second dielectric layer 308. Trench 324 is formed in a first direction (e.g., the negative y-direction) into the exposed portion of second dielectric layer 308 using patterned material layer 320 as an etch mask. In various examples, trench 324 may be formed using one or more etching processes. In various examples, the one or more etching processes may include a wet etching process, a dry etching process, or combination thereof.

Continuing with step 204, and as show in FIG. 3C, trench 324 is etched further to form an extended trench 326. In various examples, patterned material layer 320 may be further etched to alter opening 322. For example, patterned material layer 320 may be etched to extend opening 322 in a second direction (e.g., in the positive x-direction) that is perpendicular to the first direction to form extended opening 322′. In various other examples, opening 322 may further be extended in a third direction (e.g., in the negative x-direction) that is opposite the second direction to form extended opening 322′. For example, to form extended opening 322′ a second patterned material layer (not shown) may be formed over patterned material layer 320 which is then used to pattern patterned material layer 320 to form extended opening 322′.

In various examples, and as shown in FIG. 3C, patterned material layer 320 defining extended opening 322′ is used to extend trench 324 further into second dielectric layer 308 to form extended trench 326. As shown, in forming extended trench 326, trench 324 is extended in the first direction (e.g., the negative y-direction) as well as in the second and third directions (e.g., the positive x-direction and the negative x-direction). This results in extended trench 326 having a first portion 326a (or upper portion) having a first width w1 and a second portion 326b (or lower portion) having a second width w2.

In various examples, and as shown in FIG. 3C, first width w1 of extended trench 326 is greater than second width w2 of extended trench 326. In various examples, first width w1 of extended trench 326 may be about equal to second width w2 of extended trench 326. In various examples, for example when a dual damascene process is used to form extended trench 326, first portion 326a may be referred to as a trench and second portion 326b may be referred to as a via. In various examples, extended trench 326 may be formed using one or more etching processes. In various examples, extended trench 326 may be formed using different methods and process than those described above while remaining within the scope of this disclosure. For examples, extended trench 326 may be formed without first forming trench 324.

At steps 206 and 208, a barrier layer is formed within the trench and a first doped layer is formed over the barrier layer disposed within the trench. As shown in FIG. 3D, a barrier layer 328 is formed over second dielectric layer 308 and in extended trench 326, including along sidewalls and bottom surfaces of extended trench 326, including in first portion 326a and second portion 326b. In various examples, barrier layer 328 may include titanium (Ti), titanium nitride (TiN), tantalum (Ta), tantalum nitride (TaN), the like, or a combination thereof. In various examples, barrier layer 328 may be formed by a physical vapor deposition (PVD), a chemical vapor deposition (CVD) process, other suitable processing techniques, or a combination thereof.

Continuing with FIG. 3D, a first doped seed layer 330 (or first doped layer) is formed over barrier layer 328. First doped seed layer 330 (e.g., a copper seed layer) has a first thickness t1. In various examples, first thickness t1 may be about 350 Å to about 550 Å, and more specifically, about 400 Å to about 500 Å.

First doped seed layer 330 (or first doped layer) may include a metal and/or metal alloy and a first dopant. In various examples, the metal and/or metal alloy may be one of copper (Cu), tungsten (W), silver (Ag), gold (Au), aluminum (Al), the like, or any combination thereof. In various examples, the first dopant may be one of aluminum (Al), manganese (Mn), magnesium (Mg), the like, or any combination thereof. In various examples, the concentration of the first dopant in first doped seed layer 330 may be equal to or less than about 2%, and more specifically, about 0.25% to about 1.0%. In various examples, first doped seed layer 330 may be formed using physical vapor deposition (PVD), another suitable process, or combinations thereof.

At step 210, a conductive layer is formed over the first doped layer disposed within the trench. As shown in FIG. 3E, a conductive layer 332 is formed over first doped seed layer 330 disposed within extended trench 326, including within first portion 326a and second portion 326b of extended trench 326. Conductive layer 332 includes an overburden portion 332a that extends above (e.g., in the positive y-direction) a top surface of second dielectric layer 308 outside of extended trench 326. In other words, conductive layer 332 is formed within extended trench 326 and overburden portion 332a extends over and outside of extended trench 326. In various examples, conductive layer 332 may be or include a fill metal such as copper (Cu), tungsten (W), silver (Ag), gold (Au), aluminum (Al), the like, or a combination thereof. In various examples, conductive layer 332 may be formed by an electroplating process, a physical vapor deposition (PVD), a chemical vapor deposition (CVD) process, a sputtering process, other suitable processing techniques, or a combination thereof.

At step 212, a second doped layer is formed over the overburden portion of the conductive layer. As shown in FIG. 3F, a second doped seed layer 334 (or second doped layer) is formed over overburden portion 332a of conductive layer 332. Second doped seed layer 334 has a second thickness t2. In various examples, second thickness t2 may be about 350 Å to about 550 Å, and more specifically, about 400 Å to about 500 Å. In various examples, second thickness t2 may be greater than first thickness t1. In various examples, second thickness t2 may be less than first thickness t1. In various examples, second thickness t2 may be about equal to first thickness t1.

Second doped seed layer 334 may include a metal and/or metal alloy and a second dopant. The second dopant, metal, and/or metal alloy may include similar materials to those in first doped seed layer 330 described above. In various examples, the second dopant may be different than the first dopant in first doped seed layer 330. In various examples, the second dopant may be the same as the first dopant in first doped seed layer 330. In various examples, second doped seed layer 334 may have the same material composition as first doped seed layer 330.

At step 214, a thermal treatment process is performed, wherein the first and second dopants diffuse into the conductive layer during the thermal treatment process such that a doped conductive layer is formed as a result of performing the thermal process. As shown in FIG. 3G, a thermal treatment process 336 is performed during which the first dopant of first doped seed layer 330 and the second dopant of the second doped seed layer 334 diffuse into conductive layer 332 such that a doped conductive layer 338, including an overburden portion 338a, is formed as a result of thermal treatment process 336. Barrier layer 328 and doped conductive layer 338 may be collectively referred to as doped conductive feature 310.

As shown, after performing thermal treatment process 336, first doped seed layer 330 and second doped seed layer 334 may not be delineated (or distinguishable) with respect to doped conductive layer 338. That is, doped conductive layer 338 includes the material compositions of first doped seed layer 330, second doped seed layer 334, and conductive layer 332 after the thermal treatment process 336. For example, when first doped seed layer 330 and second doped seed layer 334 both include copper (Cu) as the metal (e.g., as a primary constituent) and aluminum (Al) as their dopant species and conductive layer 332 includes copper (Cu) as its metal, then doped conductive layer 338 includes copper (as a primary constituent) and aluminum (as dopant species) and/or an alloy thereof (CuAl).

In various examples, thermal treatment process 336 may be a temperature of about 100° C. to about 300° C., and more specifically, about 150° C. to about 250° C. In various examples, thermal treatment process 336 may be performed for about 15 min to about 45 min, and more specifically, about 25 min to about 35 min.

During thermal treatment process 336, the dopant in first doped seed layer 330 and second doped seed layer 334 diffuses into conductive layer 332 forming doped conductive layer 338. Specifically, the first dopant of first doped seed layer 330 diffuses into conductive layer 332 and the second dopant of second doped seed layer 334 diffuses into conductive layer 332. Additionally, because second doped seed layer 334 is positioned on overburden portion 332a the second dopant may more easily diffuse into overburden portion 332a as well. The diffusion of the second dopant from second doped seed layer 334 into overburden portion 332a may reduce diffusion of the first dopant from first doped seed layer 330 into overburden portion 332a which effectively increases the dopant concentration within doped conductive layer 338 disposed within extended trench 326. That is, during thermal treatment process 336, second doped seed layer 334 reduces the diffusion of first dopant from first doped seed layer 330 into overburden portion 332a which increases the supply (or availability/concentration) of the dopant (e.g., first and/or second dopants) within conductive layer 332 occupying second portion 326b (e.g., via) and first portion 326a (e.g., trench) of extended trench 326. The increased dopant concentration may facilitate the dopant (e.g., first and/or second dopants) diffusing into interfaces between doped conductive layer 338 and surrounding material layers (e.g., barrier layer 328, second etch stop layer 312, etc.), grain boundaries within doped conductive layer 338, and/or other defects of doped conductive layer 338.

At steps 216 and 218, the overburden of the doped conductive layer is removed, and additional processing steps are performed. As shown in FIG. 3H, a removal process is performed to remove overburden portion 338a and a portion of barrier layer 328. Specifically, overburden portion 338a of doped conductive layer 338 and the portions of barrier layer 328 that extend above a top surface of second dielectric layer 308 are removed. In various examples, a planarization process, such as a chemical mechanical polishing (CMP) process, may be used to remove overburden portion 338a and portions of barrier layer 328.

After removing overburden portion 338a and the portion of barrier layer 328, a second etch stop layer 312 (or dielectric layer) may be formed over doped conductive feature 310 and second dielectric layer 308. In various examples, second etch stop layer 312 may be or include similar materials as first etch stop layer 306, described above. Additional processing steps may be performed. For example, additional materials may be formed on and over device 300, including dielectric materials, contacts, interconnects, and the like. For examples, additional process steps may occur before, during or after method 200.

Although method 200 has been described as using two doped seed layers (e.g., first doped seed layer 330 and second doped seed layer 334), method 200 may be used with more than two doped seed layers. For example, three or more doped seed layers may be used in method 200. In various examples, a third doped seed layer may be formed over first doped seed layer 330 and/or second doped seed layer 334. In some examples, such a third doped seed layer may be formed directly on first doped seed layer 330 and/or second doped seed layer 334. In some other examples, such a third doped seed layer may be formed over and spaced apart from first doped seed layer 330 and/or second doped seed layer 334 such that portions of conductive layer 332 are formed between the third doped seed layer and the first doped seed layer 330 and/or second doped seed layer 334.

A third doped seed layer (or any additional doped seed layer) may include a metal and/or metal alloy and a third (or more) dopant. The third dopant, metal, and/or metal alloy may include similar materials to those in first doped seed layer 330 described above. In various examples, the third dopant may be different than the first dopant in first doped seed layer 330 and/or the second dopant in the second doped seed layer 334. In various examples, the third dopant may be the same as the first dopant in first doped seed layer 330 and/or second dopant in the second doped seed layer 334.

As described above, method 200 forms a doped conductive feature 310 using multiple doped seed layers. The use of multiple doped seed layers in forming doped conductive feature 310 increases the concentration of the dopant present in doped conductive layer 338 occupying extended trench 326. This reduces and/or prevents electromigration and/or other via stress issues that may otherwise occur due to insufficient amount of the dopant in doped conductive layer 338 of the doped conductive feature 310.

Additionally, using multiple doped seed layers alleviates some process constraints (e.g., spacing and size requirements) in forming doped conductive feature 310. For example, because the additional dopant is provided by second doped seed layer 334, second doped seed layer 334 lessens the design requirements of forming the doped conductive feature 310 in a dual damascene process. Specifically, because second doped seed layer 334 may be used as a source of the dopant and/or may retard the diffusion of the dopant from first doped seed layer into overburden portion 338a, second doped seed layer 334 allows for a thinner (e.g., less thick) first doped seed layer to be initially formed within second portion 326b (e.g., via) of extended trench 326. A thinner first doped seed layer 330 occupies less space within the via which prevents or reduces the chances of the first doped seed layer 330 pinching off, or closing, the opening to second portion 326b (e.g., via) of extended trench 326. As a result, the subsequently formed conductive layer 332 more adequately fills second portion 326b (e.g., via) of extended trench 326 as there is no pinch off effect from the first doped seed layer 330 preventing the conductive layer 332 from filling second portion 326b (e.g., via) of extended trench 326. Thus, the use of multiple doped seed layers in forming doped conductive feature 310 allows for a greater concentration of the dopant to be present in the doped conductive layer 338 of the doped conductive feature 310 while ameliorating the pinch off concern typically associated with using thicker doped seed layers that may provide a greater quantity of dopant atoms.

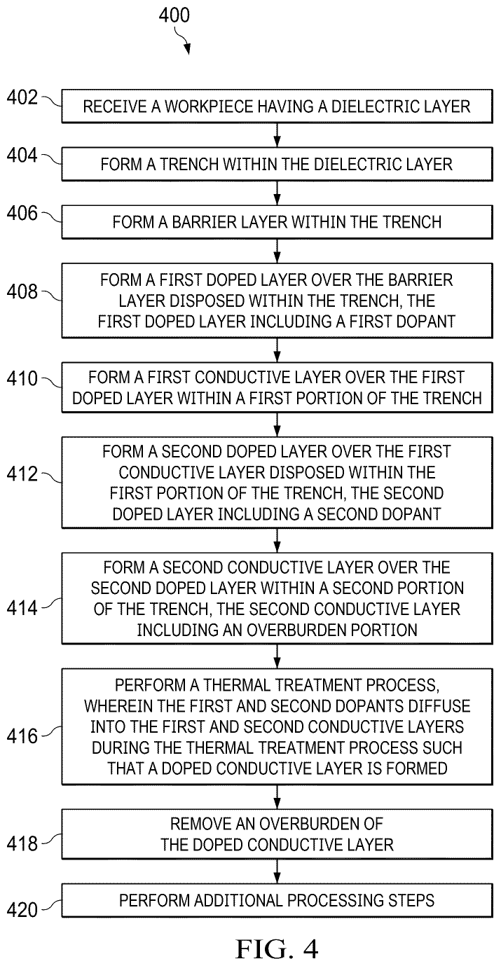

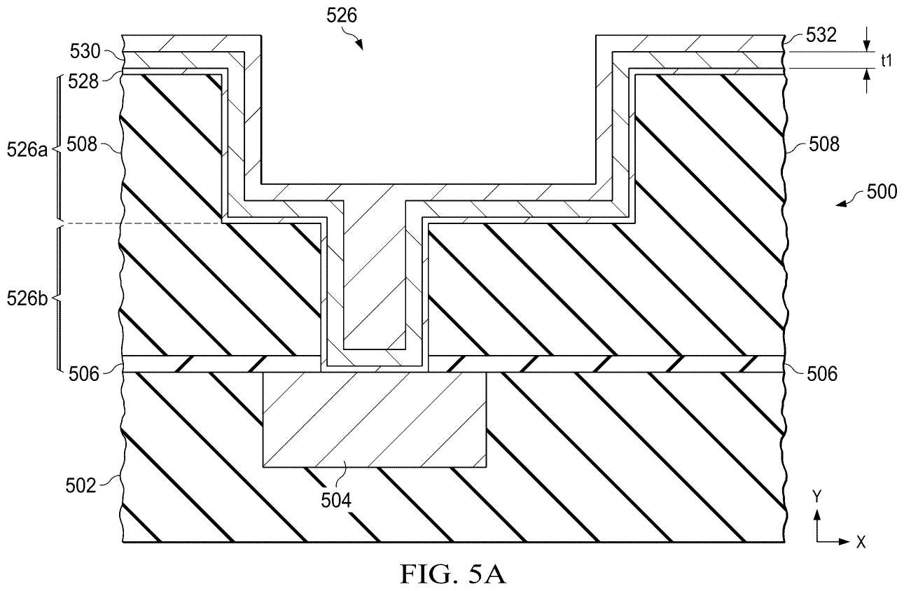

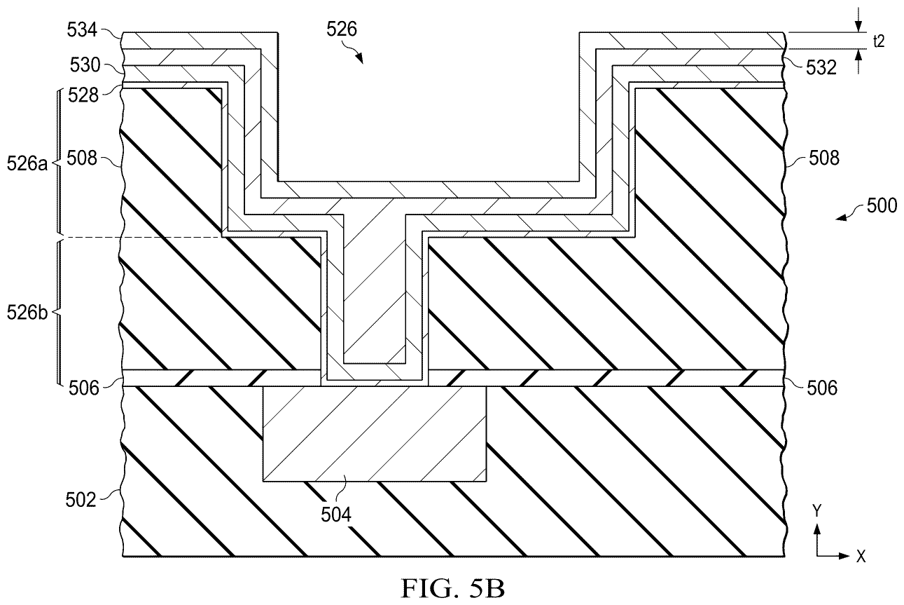

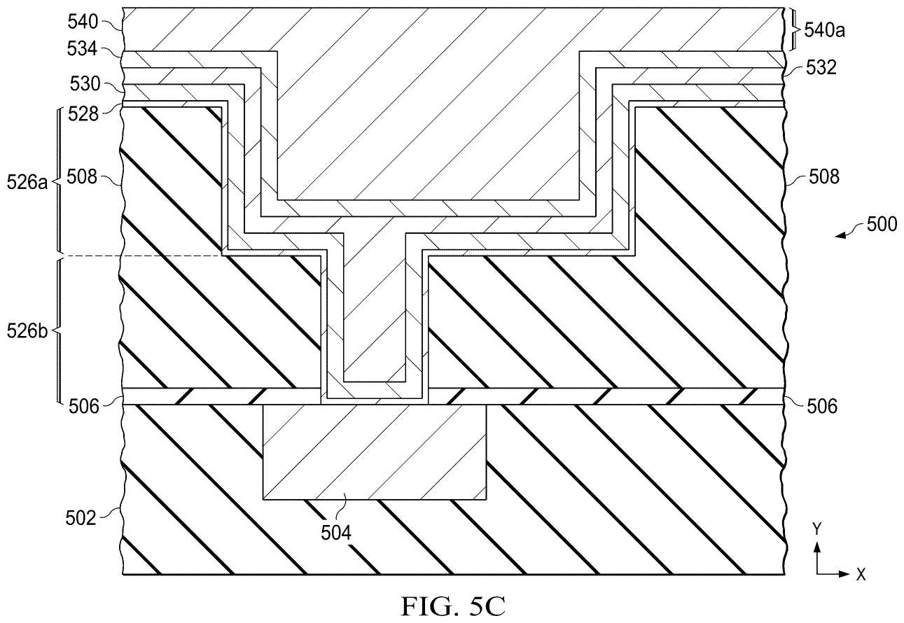

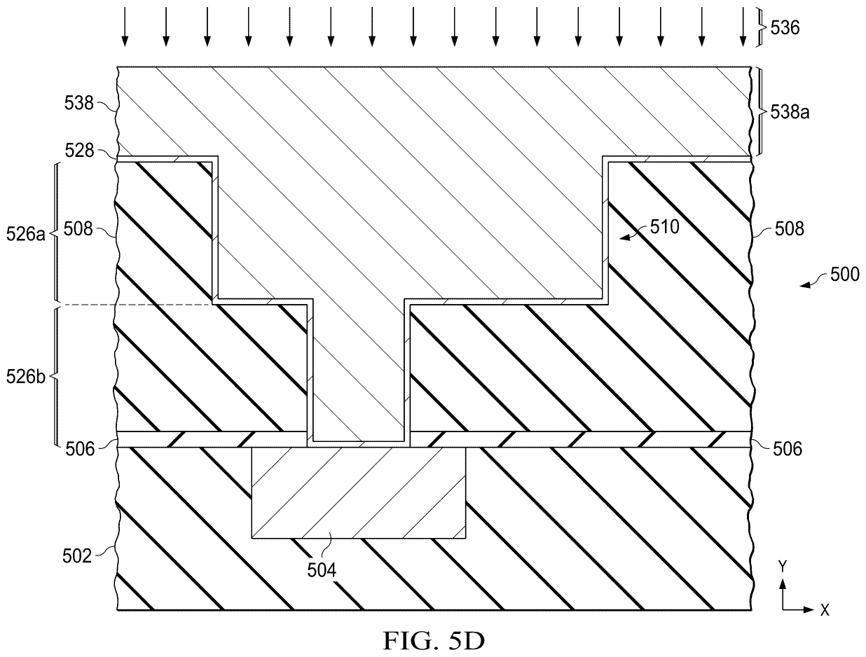

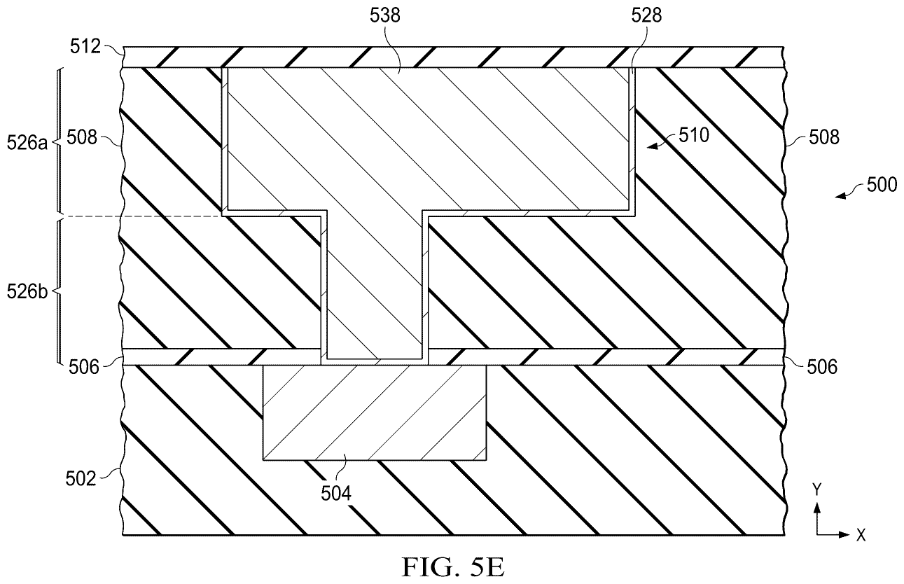

Referring now to FIG. 4, a flow diagram of a method 400 for forming an interconnect structure over a semiconductor device (e.g., a field effect transistor (FET)) is illustrated, in accordance with various examples of the present disclosure. In various examples, method 400 may be used to form an interconnect structure (e.g., interconnect structure 114) including a doped conductive feature (e.g., doped conductive feature 110) over and/or on various material layers including other dielectric layers and conductive layers associated with integrated circuit components. Additional processes can be provided before, during, and after method 400. In various examples, method 400 may be used to form a portion of device 100, described above in FIG. 1. As described below, method 400 is described with reference to FIGS. 5A-5E.

In that regard, FIGS. 5A-5E are diagrammatic cross-sectional views of a device 500 at various stages of fabrication (such as those associated with method 400 of FIG. 4) according to various aspects of the present disclosure. In various examples, device 500 may be an integrated circuit device that includes various transistors such as a field effect transistor (FET). Additional features can be added to device 500, and some features described below can be replaced, modified, or eliminated in other examples of device 500. In various examples, device 500 may be a portion of device 100 described above in FIG. 1.

Device 500 includes similar layers as device 300 described above in FIGS. 3A-3H including a first dielectric layer 502, a conductive feature 504, a first etch stop layer 506 (or dielectric layer), a second dielectric layer 508, a doped conductive feature 510, a second etch stop layer 512 (or dielectric layer), an extended trench 526 including a first portion 526a and a second portion 526b, a barrier layer 528, a first doped seed layer 530 having a first thickness t1, a second doped seed layer 534 having a second thickness t2, and a doped conductive layer 538 including an overburden portion 538a, descriptions of which may not be repeated below. Furthermore, various steps of method 400 are similar to steps of method 200 described above in FIGS. 2 and 3A-3H. Descriptions of similar steps will not be repeated below.

Referring to FIG. 4, steps 402, 404, 406, and 408 of method 400 are similar to steps 202, 204, 206, and 208, respectively, of method 200 described above in FIGS. 3A-3D. At step 402, a workpiece having a dielectric layer thereover is received. At step 404, a trench is formed within the dielectric layer. At step 406, a barrier layer is formed within the trench. At step 408, a first doped layer is formed over the barrier layer disposed within the trench. The first doped layer including a first dopant. Additional, descriptions of these similar steps of method 400 will not be repeated below, but instead are similar to steps 202, 204, 206, and 208 of method 200 described above and shown in FIGS. 3A-3D.

Referring now to FIG. 5A, at step 410, a first conductive layer is formed over the first doped layer within a first portion of the trench. As shown in FIG. 5A, device 500 includes first dielectric layer 502, conductive feature 504, first etch stop layer 506, and second dielectric layer 508 with extended trench 526 formed therein. Also shown are barrier layer 528 formed in extended trench 526 and first doped seed layer 530 formed over barrier layer 528. A first conductive layer 532 is formed over first doped seed layer 530 and filling second portion 526b (e.g., via) of extended trench 526. In various examples, first conductive layer 532 may also extend into first portion 526a (e.g., trench) of extended trench 526. As shown, first conductive layer 532 partially fills first portion 526a (e.g., trench) of extended trench 526 and extends beyond the trench over second dielectric layer 508.

In various examples, first conductive layer 532 may be or include a fill metal such as copper (Cu), tungsten (W), silver (Ag), gold (Au), aluminum (Al), the like, or a combination thereof. In various examples, first conductive layer 532 may be formed by an electroplating process, a physical vapor deposition (PVD), a chemical vapor deposition (CVD) process, a sputtering process, other suitable processing techniques, or a combination thereof.

At step 412, a second doped layer is formed over the first conductive layer disposed within the first portion of the trench. As shown in FIG. 5B, second doped seed layer 534 is formed over first conductive layer 532. Second doped seed layer 534 has a second thickness t2. In various examples, second thickness t2 may be about 350 Å to about 550 Å, and more specifically, about 400 Å to about 500 Å.

Second doped seed layer 534 may include a metal and/or metal alloy and a second dopant. In various examples, the metal and/or metal alloy may be one of copper (Cu), tungsten (W), silver (Ag), gold (Au), aluminum (Al), the like, or any combination thereof. In various examples, the second dopant may be one of aluminum (Al), manganese (Mn), magnesium (Mg), the like, or any combination thereof. In various examples, the concentration of the second dopant in second doped seed layer 534 may be equal to or less than about 2%, and more specifically, about 0.25% to about 1.0%. In various examples, second doped seed layer 534 may be formed using physical vapor deposition (PVD), another suitable process, or combinations thereof.

As described above with respect to method 200, the second dopant, metal, and/or metal alloy of second doped seed layer 534 may include similar materials to those in first doped seed layer 530. In various examples, the second dopant in second doped seed layer 534 may be different than the first dopant in first doped seed layer 530. In various examples, the second dopant in second doped seed layer 534 may be the same as the first dopant in first doped seed layer 530. In various examples, second doped seed layer 534 may have the same material composition as first doped seed layer 530.

At step 414, a second conductive layer is formed over the second doped layer within a second portion of the trench, the second conductive layer including an overburden portion. As shown in FIG. 5C, a second conductive layer 540 is formed over second doped seed layer 534 within the first portion 526a (e.g., trench) of extended trench 526. Forming second conductive layer 540 also includes forming an overburden portion 540a over a topmost surface of second dielectric layer 508. Second conductive layer 540 includes similar materials and is formed similar to first conductive layer 532 described above.

At step 416, a thermal treatment process is performed, wherein the first and second dopants diffuse into the first and second conductive layers during the thermal treatment process such that a doped conductive layer is formed as a result of performing the thermal treatment process. As shown in FIG. 5D, a thermal treatment process 536 is performed during which the first dopant of first doped seed layer 530 and the second dopant of second doped seed layer 534 diffuse into first conductive layer 532 and second conductive layer 540 such that a doped conductive layer 538, including an overburden portion 538a, is formed. Barrier layer 528 and doped conductive layer 538 may be collectively referred to as doped conductive feature 510.

As shown, after performing thermal treatment process 536, first doped seed layer 530 and second doped seed layer 534 are no longer delineated (or distinguishable) with respect to doped conductive layer 538. That is, doped conductive layer 538 includes the material compositions of first doped seed layer 530, second doped seed layer 534, first conductive layer 532, and second conductive layer 540 after thermal treatment process 536. For example, when first doped seed layer 330 and second doped seed layer 334 both include copper (Cu) as the metal (e.g., as a primary constituent) and aluminum (Al) as the dopant species and first and second conductive layers 532 and 540 both include copper (Cu) as the metal, then doped conductive layer 538 includes copper (as a primary constituent) and aluminum (as dopant species) and/or an alloy thereof (CuAl).

In various examples, thermal treatment process 536 may be a temperature of about 100° C. to about 300° C., and more specifically, about 150° C. to about 250° C. In various examples, thermal treatment process 536 may be performed for about 15 min to about 45 min, and more specifically, about 25 min to about 35 min.

During thermal treatment process 536, the dopant in first doped seed layer 530 and second doped seed layer 534 diffuse into first conductive layer 532 and second conductive layer 540 forming doped conductive layer 538. Specifically, the first dopant of first doped seed layer 530 and the second dopant of second doped seed layer 534 may diffuse into first conductive layer 532 and/or second conductive layer 540. Additionally, because second doped seed layer 534 is positioned closer to overburden portion 540a the second dopant may more easily diffuse into overburden portion 540a as well. The diffusion of the second dopant from the second doped seed layer 534 into overburden portion 540a may reduce diffusion of the first dopant from first doped seed layer 530 into overburden portion 540a which effectively increases the dopant concentration within the portion of doped conductive layer 538 occupying extended trench 526. That is, during thermal treatment process 536, second doped seed layer 534 reduces the diffusion of first dopant from first doped seed layer 530 into overburden portion 540a which increases the supply (or availability/concentration) of the dopant (e.g., first and/or second dopants) within first and second conductive layers 532 and 540 occupying second portion 526b (e.g., via) and first portion 526a (e.g., trench) of extended trench 526. The increased dopant concentration may facilitate the dopant (e.g., first and/or second dopants) diffusing into interfaces between doped conductive layer 538 and surrounding material layers (e.g., barrier layer 528, second etch stop layer 512, etc.), grain boundaries within doped conductive layer 538, and/or other defects of doped conductive layer 538.

At steps 418 and 420, the overburden of the doped conductive layer is removed, and additional processing steps are performed. As shown in FIG. 5E, a removal process is performed to remove overburden portion 538a and a portion of barrier layer 528. Specifically, overburden portion 538a of doped conductive layer 538 and the portions of barrier layer 528 that extend above a top surface of second dielectric layer 508 are removed. In various examples, a planarization process, such as a chemical mechanical polishing (CMP) process, may be used to remove overburden portion 538a and portions of barrier layer 528.

After removing overburden portion 538a and the portion of barrier layer 528, a second etch stop layer 512 (e.g., a dielectric layer) may be formed over doped conductive feature 510 and second dielectric layer 508. In various examples, second etch stop layer 512 may be or include similar materials as first etch stop layer 506, described above. Additional processing steps may be performed. For example, additional materials may be formed on and over device 500, including dielectric materials, contacts, interconnects, and the like. For examples, additional process steps may occur before, during or after method 400.

Although method 400 has been described as using two doped seed layers (e.g., first doped seed layer 530 and second doped seed layer 534), method 400 may be used with more than two doped seed layers. For example, three or more doped seed layers may be used in method 400. In various examples, a third doped seed layer may be formed over first doped seed layer 530 and/or second doped seed layer 534. In some examples, such a third doped seed layer may be formed directly on first doped seed layer 530 and/or second doped seed layer 534. In some other examples, such a third doped seed layer may be formed over and spaced apart from first doped seed layer 530 and/or second doped seed layer 534 such that portions of first conductive layer 532 and/or second conductive layer 540 are formed between such a third doped seed layer and first doped seed layer 530 and/or second doped seed layer 534.

A third doped seed layer (or any additional doped seed layer) may include a metal and/or metal alloy and a third (or more) dopant. The third dopant, metal, and/or metal alloy may include similar materials to those in first doped seed layer 530 described above. In various examples, the third dopant may be different than the first dopant in first doped seed layer 530 and/or the second dopant in the second doped seed layer 534. In various examples, the third dopant may be the same as the first dopant in first doped seed layer 530 and/or the second dopant in the second doped seed layer 534.

As described above, method 400 forms a doped conductive feature 510 using multiple doped seed layers. The use of multiple doped seed layers in forming doped conductive feature 510 increases the concentration of the dopant present in doped conductive layer 538. This reduces and/or prevents electromigration and/or other via stress issues that may otherwise occur due to insufficient amount of the dopant in doped conductive layer 538 of doped conductive feature 510.

Additionally, using multiple doped seed layers alleviates some process constraints (e.g., spacing and size requirements) in forming doped conductive feature 510. For example, because the additional dopant is provided by second doped seed layer 334, second doped seed layer 334 lessens the design requirements of forming the doped conductive feature 510 in a dual damascene process. Specifically, because second doped seed layer 534 may be used as a source of the dopant and/or may retard the diffusion of the dopant from first doped seed layer into overburden portion 538a, second doped seed layer 534 allows for a thinner (e.g., less thick) first doped seed layer to be initial formed within second portion 526b (e.g., via) of extended trench 526. A thinner first doped seed layer 530 occupies less space within the via which prevents or reduces the chances of first doped seed layer 530 pinching off, or closing, the opening to second portion 526b (e.g., via) of extended trench 526. As a result, the subsequently formed first conductive layer 532 more adequately fills second portion 526b (e.g., via) of extended trench 526 as there is no pinch off effect from first doped seed layer 530 preventing first conductive layer 532 from filling second portion 526b (e.g., via) of extended trench 526. Thus, the use of multiple doped seed layers in forming doped conductive feature 510 allows for a greater concentration of the dopant to be present in doped conductive layer 538 of doped conductive feature 510 while ameliorating the pinch off concern typically associated with using thicker doped seed layers that may provide a greater quantity of dopant atoms.

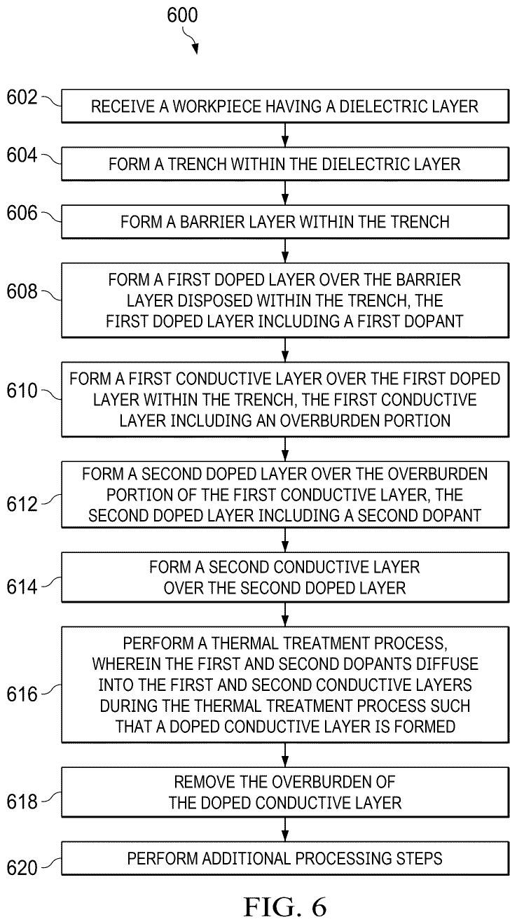

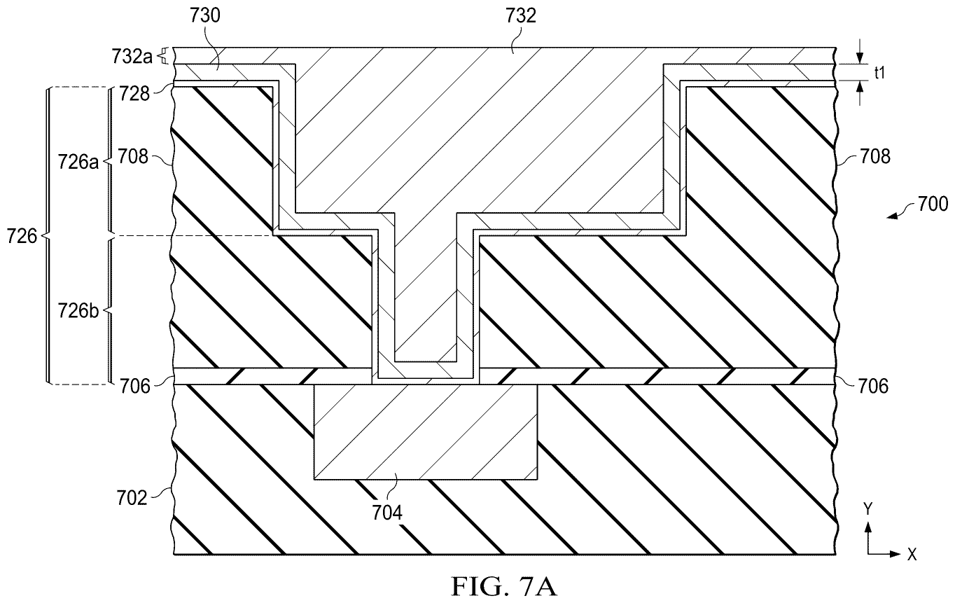

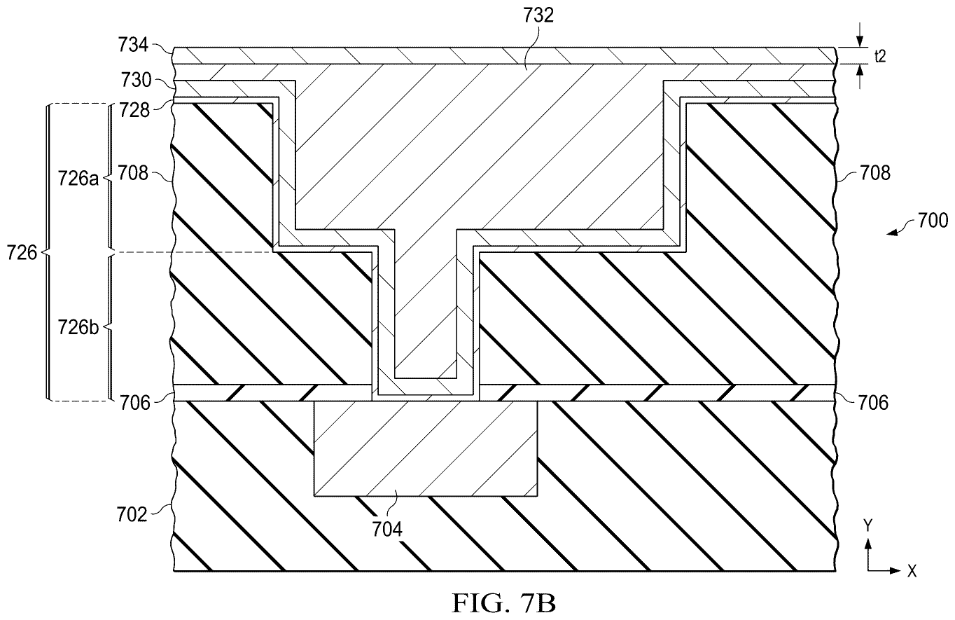

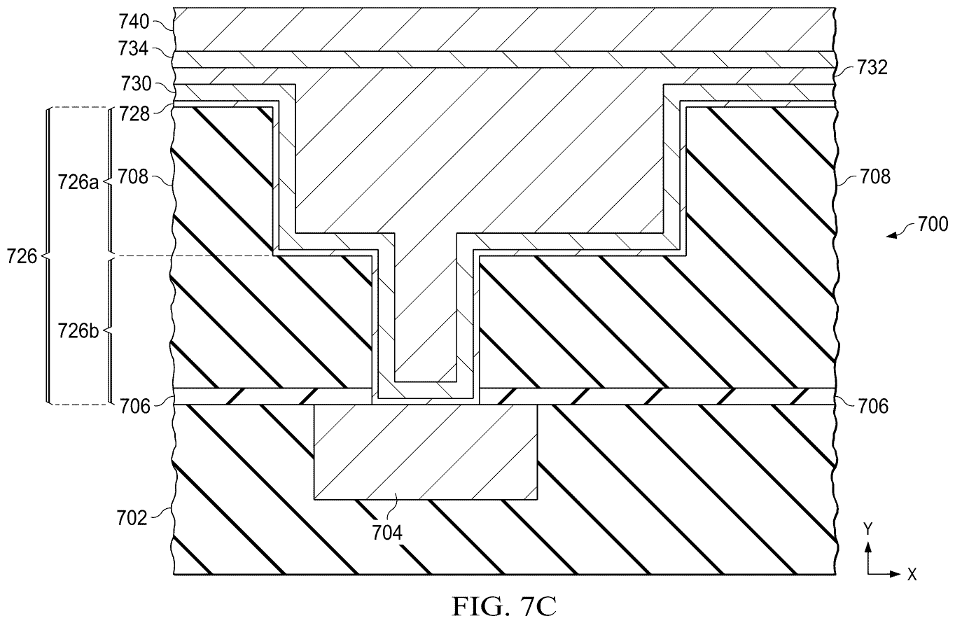

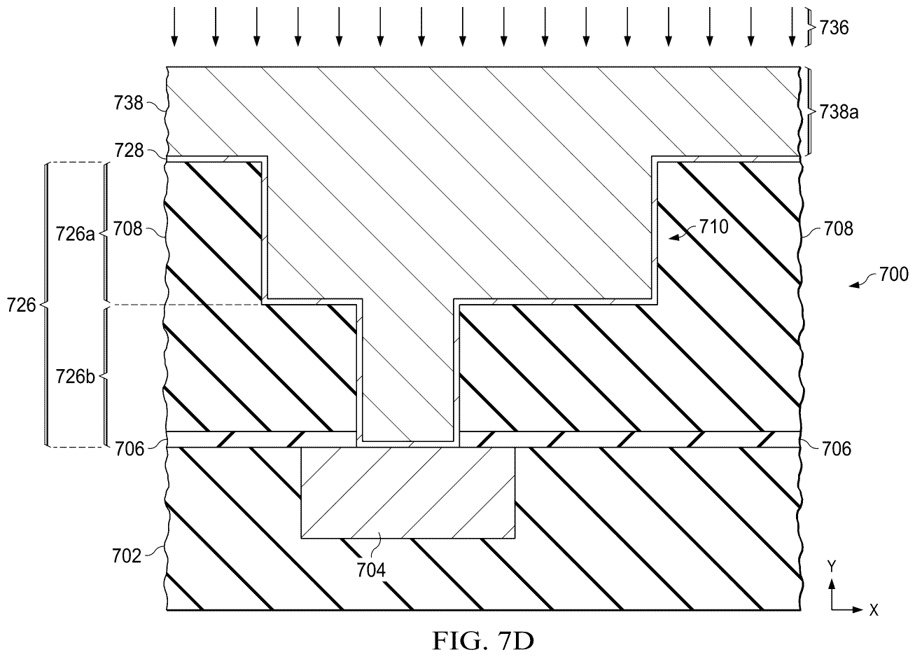

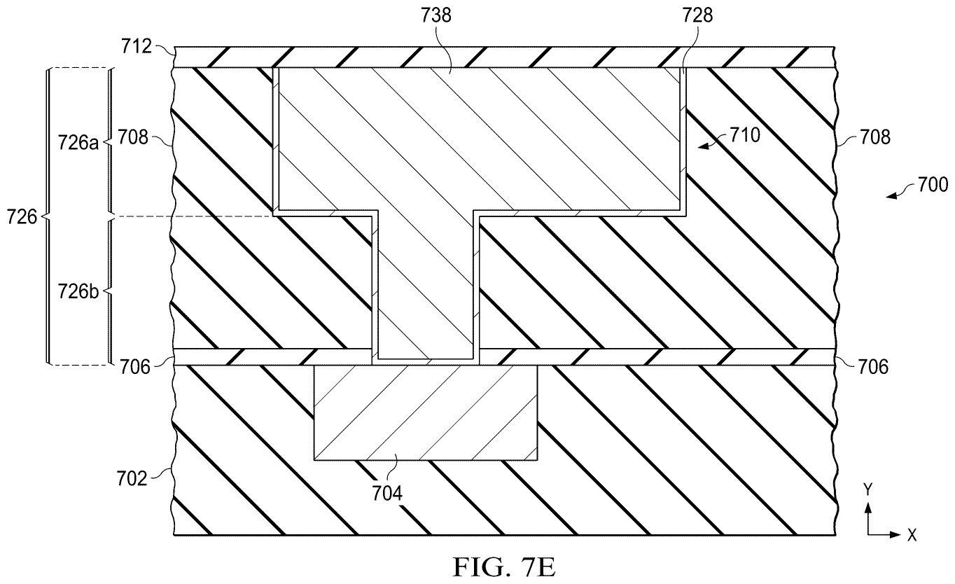

Referring now to FIG. 6, a flow diagram of a method 600 for forming an interconnect structure over a semiconductor device (e.g., a field effect transistor (FET)) is illustrated, in accordance with various examples of the present disclosure. In various examples, method 600 may be used to form an interconnect structure (e.g., interconnect structure 114) including a conductive feature (e.g., doped conductive feature 110) over and/or on various material layers including other dielectric layers and conductive layers associated with integrated circuit components. Additional processes can be provided before, during, and after method 600. In various examples, method 600 may be used to form a portion of device 100, described above in FIG. 1. As described below, method 600 is described with reference to FIGS. 7A-7E.

In that regard, FIGS. 7A-7E are diagrammatic cross-sectional views of a device 700 at various stages of fabrication (such as those associated with method 600 of FIG. 6) according to various aspects of the present disclosure. In various examples, device 700 may be an integrated circuit device that includes various transistors such as a field effect transistor (FET). Additional features can be added to device 700, and some features described below can be replaced, modified, or eliminated in other examples of device 700. In various examples, device 700 may be a portion of device 100 described above in FIG. 1.

Device 700 includes similar layers as device 300 described above in FIGS. 3A-3H including a first dielectric layer 702, a conductive feature 704, a first etch stop layer 706 (or dielectric layer), a second dielectric layer 708, a doped conductive feature 710, a second etch stop layer 712 (or dielectric layer), a barrier layer 728, a first doped seed layer 730 having a first thickness t1, a second doped seed layer 734 having a second thickness t2, and a doped conductive layer 738 including an overburden portion 738a, descriptions of which may not be repeated below. Furthermore, various steps of method 600 are similar to steps of method 200 described above in FIGS. 2 and 3A-3H. Descriptions of similar steps will not be repeated below.

Referring to FIG. 6, steps 602, 604, 606, and 608 of method 600 are similar to steps 202, 204, 206, and 208, respectively, of method 200 described above in FIGS. 3A-3D. At step 602, a workpiece having a dielectric layer is received. At step 604, a trench is formed within the dielectric layer. At step 606, a barrier layer is formed within the trench. At step 608, a first doped layer is formed over the barrier layer disposed within the trench. The first doped layer including a first dopant. Additional, descriptions of these similar steps of method 600 will not be repeated below, but instead are similar to steps 202, 204, 206, and 208 of method 200 described above and shown in FIGS. 3A-3D.

Referring now to FIG. 7A, at step 610, a first conductive layer is formed over the first doped layer within the trench, the first conductive layer including an overburden portion. As shown in FIG. 7A, device 700 includes first dielectric layer 702, conductive feature 704, first etch stop layer 706, and second dielectric layer 708. Also shown are barrier layer 728 formed in extended trench 726 (including first portion 726a and second portion 726b) and first doped seed layer 730 formed over barrier layer 728. A first conductive layer 732, including an overburden portion 732a, is formed over first doped seed layer 730. As shown first conductive layer 732 is formed within extended trench 726 and overburden portion 732a extends outside of extended trench 726 and over a top surface of second dielectric layer 708.

In various examples, first conductive layer 732 may be or include a fill metal such as copper (Cu), tungsten (W), silver (Ag), gold (Au), aluminum (Al), the like, or a combination thereof. In various examples, first conductive layer 732 may be formed by an electroplating process, a physical vapor deposition (PVD), a chemical vapor deposition (CVD) process, a sputtering process, other suitable processing techniques, or a combination thereof.

At step 612, a second doped layer is formed over the overburden portion of the first conductive layer. As shown in FIG. 7B, second doped seed layer 734 is formed over overburden portion 732a of first conductive layer 732. Second doped seed layer 734 has a second thickness t2. In various examples, second thickness t2 may be about 350 Å to about 550 Å, and more specifically, about 400 Å to about 500 Å.

Second doped seed layer 734 may include a metal and/or metal alloy and a second dopant. In various examples, the metal and/or metal alloy may be one of copper (Cu), tungsten (W), silver (Ag), gold (Au), aluminum (Al), the like, or any combination thereof. In various examples, the second dopant may be one of aluminum (Al), manganese (Mn), magnesium (Mg), the like, or any combination thereof. In various examples, the concentration of the second dopant in second doped seed layer 734 may be equal to or less than about 2%, and more specifically, about 0.25% to about 1.0%. In various examples, second doped seed layer 534 may be formed using physical vapor deposition (PVD), another suitable process, or combinations thereof.

As described above with respect to method 200, the second dopant, metal, and/or metal alloy of second doped seed layer 734 may include similar materials to those in first doped seed layer 730. In various examples, the second dopant in second doped seed layer 734 may be different than the first dopant in first doped seed layer 730. In various examples, the second dopant in second doped seed layer 734 may be the same as the first dopant in first doped seed layer 730. In various examples, second doped seed layer 734 may have the same material composition as first doped seed layer 730.

At step 614, a second conductive layer is formed over the second doped layer. As shown in FIG. 7C, a second conductive layer 740 is formed over second doped seed layer 734. Additionally, because second conductive layer 740 is disposed outside of extended trench 726, second conductive layer 740 effectively functions as part of the overburden for first conductive layer 732 as described in more detail below. Second conductive layer 740 includes similar materials and is formed similar to first conductive layer 732 described above.

At step 616, a thermal treatment process is performed, wherein the first and second dopants diffuse into the first and second conductive layers during the thermal treatment process such that a doped conductive layer is formed as a result of performing the thermal treatment process. As shown in FIG. 7D, a thermal treatment process 736 is performed during which the first dopant of first doped seed layer 730 and the second dopant of second doped seed layer 734 diffuse into first conductive layer 732 and second conductive layer 740 such that a doped conductive layer 738, including an overburden portion 738a, is formed. Barrier layer 728 and doped conductive layer 738 may be collectively referred to as doped conductive feature 710.

As shown, after performing the thermal treatment process 736, first doped seed layer 730 and second doped seed layer 734 are no longer delineated (or distinguishable) with respect to doped conductive layer 738. That is, doped conductive layer 738 includes the material compositions of first doped seed layer 730, second doped seed layer 734, first conductive layer 732, and second conductive layer 740 after thermal treatment process 736. For example, when first doped seed layer 730 and second doped seed layer 734 both include copper (Cu) as the metal (e.g., as a primary constituent) and aluminum (Al) as the dopant species and the first and second conductive layers 732 and 740 both include copper (Cu) as the metal, then doped conductive layer 738 includes copper (as a primary constituent) and aluminum (as dopant species) and/or an alloy thereof (CuAl).

In various examples, thermal treatment process 736 may be a temperature of about 100° C. to about 300° C., and more specifically, about 150° C. to about 250° C. In various examples, thermal treatment process 736 may be performed for about 15 min to about 45 min, and more specifically, about 25 min to about 35 min.

During thermal treatment process 736, the dopant in first doped seed layer 730 and second doped seed layer 734 diffuse into first conductive layer 732 and second conductive layer 740 forming doped conductive layer 738. Specifically, the first dopant of first doped seed layer 730 and the second dopant of the second doped seed layer 734 may diffuse into first conductive layer 732 and/or second conductive layer 740. Additionally, because second doped seed layer 734 is positioned within and/or on (or over) the overburden the second dopant may more easily diffuse into the overburden as well. The diffusion of the second dopant from second doped seed layer 534 into the overburden reduces diffusion of the first dopant from first doped seed layer 730 into overburden portion 738a of doped conductive layer 738 which effectively increases the dopant concentration within the portion of doped conductive layer 738 occupying extended trench 726. That is, during thermal treatment process 736, second doped seed layer 734 reduces the diffusion of the first dopant from first doped seed layer 730 into overburden portion 738a which increases the supply (or availability/concentration) of the dopant (e.g., first and/or second dopants) within first and second conductive layers 732 and 740 occupying second portion 726b (e.g., via) and first portion 726a (e.g., trench) of extended trench 726. The increased dopant concentration may facilitate the dopant (e.g., first and/or second dopants) diffusing into interfaces between doped conductive layer 738 and surrounding material layers (e.g., barrier layer 728, second etch stop layer 712, etc.), grain boundaries within doped conductive layer 738, and/or other defects of doped conductive layer 738.

At steps 618 and 620, the overburden of the doped conductive layer is removed, and additional processing steps are performed. As shown in FIG. 7E, a removal process is performed to remove overburden portion 738a and a portion of barrier layer 728. Specifically, overburden portion 738a of doped conductive layer 738 and the portions of barrier layer 728 that extend above a top surface of second dielectric layer 708 are removed. In various examples, a planarization process, such as a chemical mechanical polishing (CMP) process, may be used to remove overburden portion 738a and portions of barrier layer 728.

After removing overburden portion 738a and the portion of barrier layer 728, a second etch stop layer 712 (e.g., a dielectric layer) may be formed over doped conductive feature 710 and second dielectric layer 708. In various examples, second etch stop layer 712 may be or include similar materials as first etch stop layer 706, described above. Additional processing steps may be performed. For example, additional materials may be formed on and over device 700, including dielectric materials, contacts, interconnects, and the like. For examples, additional process steps may occur before, during or after method 600.

Although method 600 has been described as using two doped seed layers (e.g., first doped seed layer 730 and second doped seed layer 734), method 600 may be used with more than two doped seed layers. For example, three or more doped seed layers may be used in method 600. In various examples, a third doped seed layer may be formed over first doped seed layer 730 and/or second doped seed layer 734. In some examples, such a third doped seed layer may be formed directly on first doped seed layer 730 and/or second doped seed layer 734. In some other examples, such a third doped seed layer may be formed over and spaced apart from first doped seed layer 730 and/or second doped seed layer 734 such that portions of first conductive layer 732 and/or second conductive layer 740 are formed between such a third doped seed layer and first doped seed layer 730 and/or second doped seed layer 734.

A third doped seed layer (or any additional doped seed layer) may include a metal and/or metal alloy and a third (or more) dopant. The third dopant, metal, and/or metal alloy may include similar materials to those in first doped seed layer 730 described above. In various examples, the third dopant may be different than the first dopant in first doped seed layer 730 and/or the second dopant in the second doped seed layer 734. In various examples, the third dopant may be the same as the first dopant in first doped seed layer 730 and/or the second dopant in the second doped seed layer 734.

As described above, method 600 forms a doped conductive feature 710 using multiple doped seed layers. The use of multiple doped seed layers in forming the doped conductive feature 710 increases the concentration of the dopant present in the doped conductive layer 738 occupying extended trench 726. This results in preventing or reducing electromigration and/or other via stress issues that may otherwise occur due to insufficient amount of the dopant in doped conductive layer 738 of doped conductive feature 710.

Additionally, using multiple doped seed layers also alleviates some process constraints (e.g., spacing and size requirements) in forming doped conductive feature 710. For example, because the additional dopant is provided by second doped seed layer 734 this lessens the design requirements of forming the doped conductive feature 710 in a dual damascene process. Specifically, because second doped seed layer 734 may be used as a source of the dopant and/or may retard the diffusion of the dopant from first doped seed layer into overburden portion 738a this allows for a thinner (e.g., less thick) first doped seed layer to be initial formed within second portion 726b (e.g., via) of extended trench 726. A thinner first doped seed layer 730 occupies less space within the via which prevents or reduces the occurrence of the first doped seed layer 730 pinching off, or closing, the opening to second portion 726b (e.g., via) of extended trench 526. As a result, the subsequently formed first conductive layer 732 more adequately fills second portion 726b (e.g., via) of extended trench 726 as there is no pinch off effect from the first doped seed layer 730 preventing first conductive layer 732 from filling second portion 726b (e.g., via) of extended trench 726. Thus, the use of multiple doped seed layers in forming doped conductive feature 710 allows for a greater concentration of the dopant to be present in the doped conductive layer 738 of the doped conductive feature 710 while ameliorating the pinch off concern typically associated with using thicker doped seed layers that may provide a greater quantity of dopant atoms.

Accordingly, the methods and devices disclosed herein provide an improved interconnect structure for use in integrated circuit components that help resolve electromigration issues, help manage via stresses, and improve structural reliability in an integrated circuit device. Generally, disclosed herein are methods of forming a doped conductive feature of an interconnect structure using multiple doped seed layers. The use of multiple doped seed layers in forming the doped conductive feature increases the concentration of the dopant in the doped conductive layer of the doped conductive feature. This results in preventing or reducing electromigration and/or other via stresses that may otherwise occur due to insufficient amount of the dopant present in the doped conductive layer of the doped conductive feature.

Additionally, using multiple doped seed layers alleviates some process constraints (e.g., spacing and size requirements) in forming the doped conductive feature. For example, a thick single doped seed layer may be used to provide the desired concentration of the dopant for forming a doped conductive feature. However, the thick doped seed layer may present process challenges especially when forming doped conductive features in smaller, or narrower, vias because the thick doped seed layer may pinch off the opening to the via. Because the present disclosure implements multiple doped seed layers, the design requirements of forming a thicker doped seed layer in vias are removed, for example in a dual damascene process, due to the additional dopant provided by a second (or more) doped layer disposed over the via.

Specifically, two (or more) doped seed layers, being used as a source of the dopant, allow for a thinner (e.g., less thick) first doped seed layer to be used within a via during a dual damascene process. A thinned (or thinner) first doped seed layer occupies less space within the via which reduces the chances of the first doped seed layer pinching off, or closing, the opening to the via. As a result, the subsequently formed conductive layer of the doped conductive feature more adequately fills the via as there is no pinch off effect from the first doped seed layer preventing the conductive layer from filling the via. Moreover, because a second (or more) doped seed layer is formed over the via the desired dopant concentration within the doped conductive feature can still be achieve even though a thinner (e.g., containing a lower amount of dopant in view of a less total volume of the doped seed layer) first doped seed layer is formed within the via as part of forming the doped conductive feature. Thus, the use of multiple doped seed layers in forming a doped conductive feature allows for a greater concentration of the dopant to be present in the doped conductive layer of the doped conducting feature while ameliorating the pinch off concern typically associated with using thicker doped seed layers that may provide a greater quantity of dopant atoms.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A method comprising:
forming a trench within a dielectric layer, the trench including a first portion having a first width and a second portion having a second width that is different than the first width;
forming a first doped layer in the trench;
forming a first conductive material in at least the first portion of the trench;
forming a second doped layer over the first conductive material, the second doped layer including a dopant; and
performing a thermal treatment process, wherein the dopant of the second doped layer diffuses into the first conductive material during the thermal treatment process such that a doped conductive material is formed as a result of performing the thermal treatment process.

2. The method of claim 1, further comprising:
forming another dielectric layer over the doped conductive material.

3. The method of claim 1, wherein the first conductive material includes copper (Cu) and the dopant includes aluminum (Al), manganese (Mn), magnesium (Mg), or a combination thereof.

4. The method of claim 1, wherein forming the first conductive material in at least the first portion of the trench further includes forming the first conductive material in the second portion of the trench.

5. The method of claim 1, further comprising:
forming a second conductive material over the second doped layer prior to performing the thermal treatment process.

6. The method of claim 5, wherein forming the second doped layer over the first conductive material includes forming the second doped layer within the second portion of the trench directly on the first conductive material, and
wherein forming the second conductive material over the second doped layer prior to performing the thermal treatment process includes forming the second conductive material directly on the second doped layer disposed within the second portion of the trench.

7. The method of claim 1, wherein the first doped layer includes the dopant, and wherein the dopant of the first doped layer diffuses into the first conductive material during the thermal treatment process.

8. The method of claim 1, wherein the first doped layer includes a first dopant and the dopant of the second doped layer is a second dopant, the second dopant being different than the first dopant, and
wherein the first dopant of the first doped layer diffuses into the first conductive material during the thermal treatment process.

9. A method comprising:
forming a trench within a dielectric layer;
forming a first metal layer at least partially in the trench;
forming a first doped layer over the first metal layer, the first doped layer including a first dopant; and
performing a treatment process, wherein the first dopant of the first doped layer diffuses into the first metal layer during the treatment process such that a doped metal layer is formed as a result of performing the treatment process.

10. The method of claim 9, wherein a portion of the first metal layer is disposed outside of the trench and over the dielectric layer, and
wherein forming the first doped layer over the first metal layer includes forming the first doped layer directly on the portion of the first metal layer.

11. The method of claim 9, further comprising:
performing a planarization process to remove a portion of the doped metal layer after performing the treatment process.

12. The method of claim 9, further comprising:
forming a second metal layer over the first doped layer prior to preforming the treatment process.

13. The method of claim 12, wherein the first metal layer and the second metal layer have the same material composition.

14. The method of claim 9, wherein the first metal layer includes copper (Cu) and the first dopant includes aluminum (Al), manganese (Mn), magnesium (Mg), or a combination thereof.

15. The method of claim 9, wherein performing the treatment process includes performing an annealing process at a temperature equal to or less than about 300° C.

16. The method of claim 9, further comprising:
forming a barrier layer in the trench; and
forming a second doped layer over the barrier layer within the trench prior to forming the first metal layer in the trench, the second doped layer including a second dopant.

17. The method of claim 16,
wherein the second dopant of the second doped layer diffuses into the first metal layer during the treatment process.

18. The method of claim 9, wherein forming the first metal layer at least partially in the trench includes performing an electroplating process.

19. A method comprising:
forming a first doped layer, the first doped layer including a first dopant;
forming a first conductive layer over the first doped layer;
forming a second doped layer over the first conductive layer, the second doped layer including a second dopant;
forming a second conductive layer over the second doped layer; and
after forming the second conductive layer, performing a treatment process, wherein the first and second dopants diffuse into the first conductive layer and the second conductive layer such that a doped conductive material is formed as a result of performing the treatment process.

20. The method of claim 19, wherein the first conductive layer and the second conductive layer have the same material composition, and
wherein the first dopant and the second dopant are the same.

21. The method of claim 19, wherein the first conductive layer and the second conductive layer have the same material composition, and
wherein the first dopant and the second dopant are different.

22. The method of claim 19, wherein the first doped layer includes a first copper-containing material,
wherein the first conductive layer includes a second copper-containing material; and
wherein the second doped layer includes a third copper-containing material.

23. The method of claim 19, wherein at least one of the first dopant and the second dopant is aluminum.

24. The method of claim 19, wherein forming the first conductive layer over the first doped layer includes performing a first electroplating process, and
wherein forming the second conductive layer over the second doped layer includes performing a second electroplating process.

25. The method of claim 19, further comprising:
removing a first portion of the doped conductive material after performing the treatment process, wherein a second portion of the doped conductive material remains after removing the first portion of the doped conductive material; and
forming a dielectric layer directly on the second portion of the doped conductive material.

26. The method of claim 25, wherein the dielectric layer includes silicon carbon nitride.

27. The method of claim 19, wherein the second dopant in the second doped layer has a concentration of equal to or less than about 2%.
